(19) United States
(12) Patent Application Publication
(10) Pub. No.: US 2007/0243709 A1
(43) Pub. Date: Oct. 18, 2007

(54) Planarization of substrates at a high polishing rate using electrochemical mechanical polishing

(75) Inventors: Alain Duboust, Sunnyvale, CA (US); Wei-Yung Hsu, Santa Clara, CA (US); Feng Q. Liu, San Jose, CA (US); Yan Wang, Sunnyvale, CA (US); Zhihong Wang, Santa Clara, CA (US)

Correspondence Address: PATTERSON & SHERIDAN, LLP, 3040 POST OAK BOULEVARD, SUITE 1500, HOUSTON, TX, 77056, US

(73) Assignee: Applied Materials, Inc.

(21) Appl. No.: 11/404,524

(22) Filed: Apr. 14, 2006

(51) Int. Cl. H01L 21/461; B23H 9/00

(52) U.S. Cl. 438/692; 438/693; 205/640; 205/642; 205/646

(57) ABSTRACT

A method and apparatus for removing conductive material from a substrate surface are provided. In one embodiment, a method is provided for electrochemical mechanical polishing of a substrate. A substrate comprising dielectric feature definitions, a barrier material disposed on the feature definitions, and a bulk conductive material in an amount sufficient to fill the feature definitions is provided. The substrate is exposed to an electrolyte solution. A passivation layer is formed on the conductive material. The passivation strength of the passivation layer is increased by polishing the substrate with a first voltage for a first time period. The substrate is polished with a second voltage higher than the first voltage for a second time period. Conductive material is removed from at least a portion of the substrate surface by anodic dissolution.

### BACKGROUND OF THE INVENTION

1. Field of the Invention

Embodiments of the present invention generally relate to a method for electrochemical processing.

2. Description of the Related Art

Electrochemical mechanical planarizing (ECMP) is a technique used to remove conductive materials from a substrate surface by electrochemical dissolution while concurrently polishing the substrate with reduced mechanical abrasion compared to conventional planarization processes. Electrochemical dissolution is performed by applying a bias between a cathode and a substrate surface to remove conductive materials from the substrate surface into a surrounding electrolyte. Typically, the bias is applied to the substrate surface by a conductive polishing material on which the substrate is processed. A mechanical component of the polishing process is performed by providing relative motion between the substrate and the conductive polishing material that enhances the removal of the conductive material from the substrate.

Increased substrate throughput using ECMP is highly desirable. However attempts to increase substrate throughput by increasing the bias applied to the substrate surface can lead to a decrease in planarization efficiency and a corresponding increase in hollow metal and corrosion defects. Planarization efficiency is defined as a reduction of the step height of a deposited material. In the ECMP process, planarization efficiency is a function of the bias applied between the substrate surface and the cathode. The higher the bias, the higher the polishing rate and the poorer the planarization efficiency. Whereas a lower bias with a lower polishing rate leads to better planarization efficiency but also leads to a decrease in throughput.

Thus, there is a need for an improved method and apparatus for electrochemical processing of metal and barrier materials which increases substrate throughput while maintaining improved planarization efficiency.

### SUMMARY OF THE INVENTION

Embodiments of the invention generally provide a method and apparatus for removing conductive material from a substrate surface. In one embodiment, a method is provided for electrochemical mechanical polishing of a substrate. A substrate comprising dielectric feature definitions, a barrier material disposed on the feature definitions, and a bulk conductive material in an amount sufficient to fill the feature definitions is provided. The substrate is exposed to an electrolyte solution. A passivation layer is formed on the conductive material. The passivation strength of the passivation layer is increased by polishing the substrate with a first voltage for a first time period. The substrate is polished with a second voltage higher than the first voltage for a second time period. Conductive material is removed from at least a portion of the substrate surface by anodic dissolution.

In another embodiment, a method of processing a substrate having a conductive material layer disposed thereon is provided. A substrate is provided to a process apparatus. The substrate is exposed to an electrolyte. A current suppression layer is formed on the substrate. A polishing article contacts the substrate. A first relative motion is provided between the substrate and the polishing article. A bias is applied to the substrate for a first time period. The density of the current suppression layer is increased. A first portion of the conductive material layer is removed. A second relative motion between the substrate and the polishing article is provided. A second bias higher than the first bias is applied to the substrate for a second time period. A second portion of the conductive material layer is removed.

In yet another embodiment a method for electrochemically and mechanically planarizing a surface of a substrate is provided. The substrate is held against a polishing pad of a polishing device. A first potential between about 1.5 volts and about 3.0 volts for a time period between about 5 seconds and about 10 seconds is applied between the polishing pad and the surface of the substrate being planarized. A second potential between about 4.5 volts and about 5.5 volts for a time period between about 5 seconds and about 90 seconds is applied between the polishing pad and the surface of the substrate being planarized.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a plan view of an electrochemical mechanical planarizing system;

FIG. 2 is a sectional view of one embodiment of a first electrochemical mechanical planarizing (ECMP) station of the system of FIG. 1;

FIG. 3A is a partial sectional view of the bulk ECMP station through two contact assemblies;

FIGS. 3B-C are sectional views of alternative embodiments of contact assemblies;

FIG. 3D-E are sectional views of plugs;

FIGS. 4 are side, exploded and sectional views of one embodiment of a contact assembly;

FIG. 5 is one embodiment of a contact element;

FIG. 6 is a perspective view of another embodiment of another ECMP station;

FIG. 7 is a flow chart of one embodiment of an electrochemical mechanical polishing process;

FIG. 8 is a graph depicting passivation strength-voltage characteristics of the electrochemical polishing process of the present invention;

FIGS. 9A-C are graphs showing various waveforms depicting voltage-time characteristics of the electrochemical polishing process of the present invention; and

FIG. 10 is a graph showing a waveform depicting voltage-time characteristics of the electrochemical polishing process of the present invention.

### DETAILED DESCRIPTION

Embodiments for a system and method for removal of conductive and barrier materials from a substrate are provided. Although the embodiments disclosed below focus primarily on removing material from, e.g., planarizing, a substrate, it is contemplated that the teachings disclosed herein may be used to electroplate a substrate by reversing the polarity of an electrical bias applied between the substrate and an electrode of the system.

Apparatus

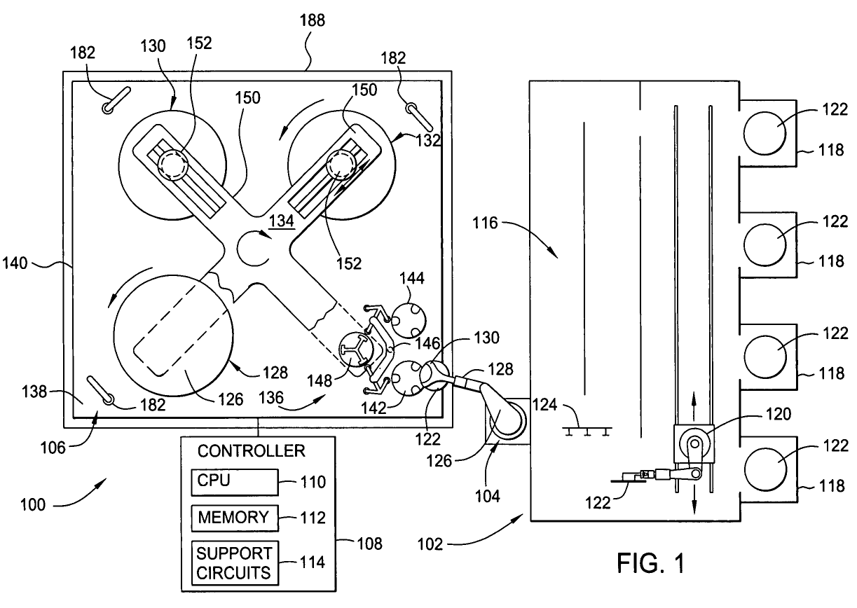

FIG. 1 is a plan view of one embodiment of a planarization system 100 having an apparatus for electrochemically processing a substrate. The exemplary system 100 generally comprises a factory interface 102, a loading robot 104, and a planarizing module 106. The loading robot 104 is disposed proximate the factory interface 102 and the planarizing module 106 to facilitate the transfer of substrates 122 therebetween.

A controller 108 is provided to facilitate control and integration of the modules of the system 100. The controller 108 comprises a central processing unit (CPU) 110, a memory 112, and support circuits 114. The controller 108 is coupled to the various components of the system 100 to facilitate control of, for example, the planarizing, cleaning, and transfer processes.

The factory interface 102 generally includes a cleaning module 116 and one or more wafer cassettes 118. An interface robot 120 is employed to transfer substrates 122 between the wafer cassettes 118, the cleaning module 116 and an input module 124. The input module 124 is positioned to facilitate transfer of substrates 122 between the planarizing module 106 and the factory interface 102 by grippers, for example vacuum grippers or mechanical clamps.

The planarizing module 106 includes at least a first electrochemical mechanical planarizing (ECMP) station 128, disposed in an environmentally controlled enclosure 188. Examples of planarizing modules 106 that can be adapted to benefit from the invention include MIRRA®, MIRRA MESA™, REFLEXION®, REFLEXION® LK, and REFLEXION LK Ecmp™ Chemical Mechanical Planarizing Systems, all available from Applied Materials, Inc. of Santa Clara, Calif. Other planarizing modules, including those that use processing pads, planarizing webs, or a combination thereof, and those that move a substrate relative to a planarizing surface in a rotational, linear, or other planar motion may also be adapted to benefit from the invention.

In the embodiment depicted in FIG. 1, the planarizing module 106 includes the first ECMP station 128, a second ECMP station 130, and a third ECMP station 132. Bulk removal of conductive material disposed on the substrate 122 may be performed through an electrochemical dissolution process at the first ECMP station 128. After the bulk material removal at the first ECMP station 128, the remaining conductive material is removed from the substrate at the second ECMP station 130 through a multi-step electrochemical mechanical process, wherein part of the multi-step process is configured to remove residual conductive material. It is contemplated that more than one ECMP station may be utilized to perform the multi-step removal process after the bulk removal process performed at a different station. Alternatively, each of the first and second ECMP stations 128, 130 may be utilized to perform both the bulk and multi-step conductive material removal on a single station. It is also contemplated that all ECMP stations (for example 3 stations of the module 106 depicted in FIG. 1) may be configured to process the conductive layer with a two step removal process.

The exemplary planarizing module 106 also includes a transfer station 136 and a carousel 134 that are disposed on an upper or first side 138 of a machine base 140. In one embodiment, the transfer station 136 includes an input buffer station 142, an output buffer station 144, a transfer robot 146, and a load cup assembly 148. The input buffer station 142 receives substrates from the factory interface 102 by means of the loading robot 104. The loading robot 104 is also utilized to return polished substrates from the output buffer station 144 to the factory interface 102. The transfer robot 146 is utilized to move substrates between the buffer stations 142, 144 and the load cup assembly 148.

In one embodiment, the transfer robot 146 includes two gripper assemblies, each having pneumatic gripper fingers that hold the substrate by the substrate's edge. The transfer robot 146 may simultaneously transfer a substrate to be processed from the input buffer station 142 to the load cup assembly 148 while transferring a processed substrate from the load cup assembly 148 to the output buffer station 144. An example of a transfer station that may be used to advantage is described in U.S. Pat. No. 6,156,124, issued Dec. 5, 2000, which is herein incorporated by reference in its entirety.

The carousel 134 is centrally disposed on the base 140. The carousel 134 typically includes a plurality of arms 150, each supporting a planarizing head assembly 152. Two of the arms 150 depicted in FIG. 1 are shown in phantom such that the transfer station 136 and a planarizing surface 126 of the first ECMP station 128 may be seen. The carousel 134 is indexable such that the planarizing head assemblies 152 may be moved between the planarizing stations 128, 130, 132 and the transfer station 136. One carousel that may be utilized to advantage is described in U.S. Pat. No. 5,804,507, issued Sep. 8, 1998, which is hereby incorporated by reference in its entirety.

A conditioning device 182 is disposed on the base 140 adjacent each of the planarizing stations 128, 130, 132. The conditioning device 182 periodically conditions the planarizing material disposed in the stations 128, 130, 132 to maintain uniform planarizing results.

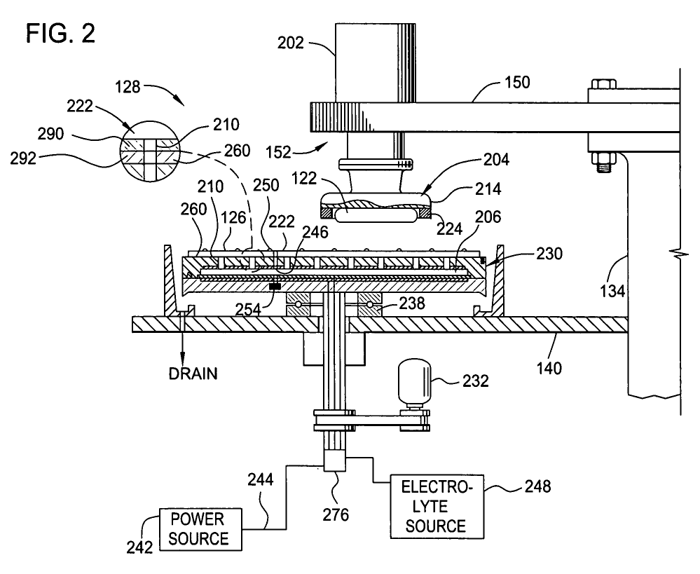

FIG. 2 depicts a sectional view of one of the planarizing head assemblies 152 positioned over one embodiment of the first ECMP station 128. The second and third ECMP stations 130, 132 may be similarly configured. The planarizing head assembly 152 generally comprises a drive system 202 coupled to a planarizing head 204. The drive system 202 generally provides at least rotational motion to the planarizing head 204. The planarizing head 204 additionally may be actuated toward the first ECMP station 128 such that the substrate 122 retained in the planarizing head 204 may be disposed against the planarizing surface 126 of the first ECMP station 128 during processing. The drive system 202 is coupled to the controller 108 that provides a signal to the drive system 202 for controlling the rotational speed and direction of the planarizing head 204.

In one embodiment, the planarizing head may be a TITAN HEAD™ or TITAN PROFILER™ wafer carrier manufactured by Applied Materials, Inc. Generally, the planarizing head 204 comprises a housing 214 and retaining ring 224 that defines a center recess in which the substrate 122 is retained. The retaining ring 224 circumscribes the substrate 122 disposed within the planarizing head 204 to prevent the substrate from slipping out from under the planarizing head 204 while processing. The retaining ring 224 can be made of plastic materials such as PPS, PEEK, and the like, or conductive materials such as stainless steel, Cu, Au, Pd, and the like, or some combination thereof. It is further contemplated that a conductive retaining ring 224 may be electrically biased to control the electric field during ECMP. Conductive or biased retaining rings tend to slow the polishing rate proximate the edge of the substrate. It is contemplated that other planarizing heads may be utilized.

The first ECMP station 128 generally includes a platen assembly 230 that is rotationally disposed on the base 140. The platen assembly 230 is supported above the base 140 by a bearing 238 so that the platen assembly 230 may be rotated relative to the base 140. An area of the base 140 circumscribed by the bearing 238 is open and provides a conduit for the electrical, mechanical, pneumatic, control signals and connections communicating with the platen assembly 230.

Conventional bearings, rotary unions and slip rings, collectively referred to as rotary coupler 276, are provided such that electrical, mechanical, fluid, pneumatic, control signals and connections may be coupled between the base 140 and the rotating platen assembly 230. The platen assembly 230 is typically coupled to a motor 232 that provides the rotational motion to the platen assembly 230. The motor 232 is coupled to the controller 108 that provides a signal for controlling for the rotational speed and direction of the platen assembly 230.

A top surface 260 of the platen assembly 230 supports a processing pad assembly 222 thereon. The processing pad assembly may be retained to the platen assembly 230 by magnetic attraction, vacuum, clamps, adhesives and the like.

A plenum 206 is defined in the platen assembly 230 to facilitate uniform distribution of electrolyte to the planarizing surface 126. A plurality of passages, described in greater detail below, are formed in the platen assembly 230 to allow electrolyte, provided to the plenum 206 from an electrolyte source 248, to flow uniformly though the platen assembly 230 and into contact with the substrate 122 during processing. It is contemplated that different electrolyte compositions may be provided during different stages of processing or at different ECMP stations 128, 130, 132.

The processing pad assembly 222 includes an electrode 292 and at least a planarizing portion 290. The electrode 292 is typically comprised of a conductive material, such as stainless steel, copper, aluminum, gold, silver and tungsten, among others. The electrode 292 may be solid, impermeable to electrolyte, permeable to electrolyte or perforated. At least one contact assembly 250 extends above the processing pad assembly 222 and is adapted to electrically couple the substrate being processing on the processing pad assembly 222 to the power source 242. The electrode 292 is also coupled to the power source 242 so that an electrical potential may be established between the substrate and electrode 292.

A meter 244 is provided to detect a metric indicative of the electrochemical process. The meter 244 may be coupled or positioned between the power source 242 and at least one of the electrode 292 or contact assembly 250. The meter 244 may also be integral to the power source 242. In one embodiment, the meter 244 is configured to provide the controller 108 with a metric indicative of processing, such a charge, current and/or voltage. This metric may be utilized by the controller 108 to adjust the processing parameters in-situ or to facilitate endpoint or other process stage detection.

A window 246 is provided through the processing pad assembly 222 and/or platen assembly 230, and is configured to allow a sensor 254, positioned below the pad assembly 222, to sense a metric indicative of polishing performance. For example, the sensor 254 may be an eddy current sensor or an interferometer, among other sensors. The metric, provided by the sensor 254 to the controller 108, provides information that may be utilized for processing profile adjustment in-situ, endpoint detection or detection of another point in the electrochemical process. In one embodiment, the sensor 254 an interferometer capable of generating a collimated light beam, which during processing, is directed at and impinges on a side of the substrate 122 that is being polished. The interference between reflected signals is indicative of the thickness of the conductive layer of material being processed. One sensor that may be utilized to advantage is described in U.S. Pat. No. 5,893,796, issued Apr. 13, 1999, which is hereby incorporated by reference in its entirety.

Embodiments of the processing pad assembly 222 suitable for removal of conductive material from the substrate 122 may generally include a planarizing surface 126 that is substantially dielectric. Other embodiments of the processing pad assembly 222 suitable for removal of conductive material from the substrate 122 may generally include a planarizing surface 126 that is substantially conductive. At least one contact assembly 250 is provided to couple the substrate to the power source 242 so that the substrate may be biased relative to the electrode 292 during processing. Apertures 210, formed through the planarizing layer 290, allow the electrolyte to establish a conductive path between the substrate 122 and electrode 292.

In one embodiment, the planarizing portion 290 of the processing pad assembly 222 is a dielectric, such as polyurethane. Examples of processing pad assemblies that may be adapted to benefit from the invention are described in U.S. Pat. No. 6,991,528, issued Feb. 5, 2004 and United States Patent Application Publication No. 2004/0020789, published Feb. 5, 2004, both of which are hereby incorporated by reference in their entireties.

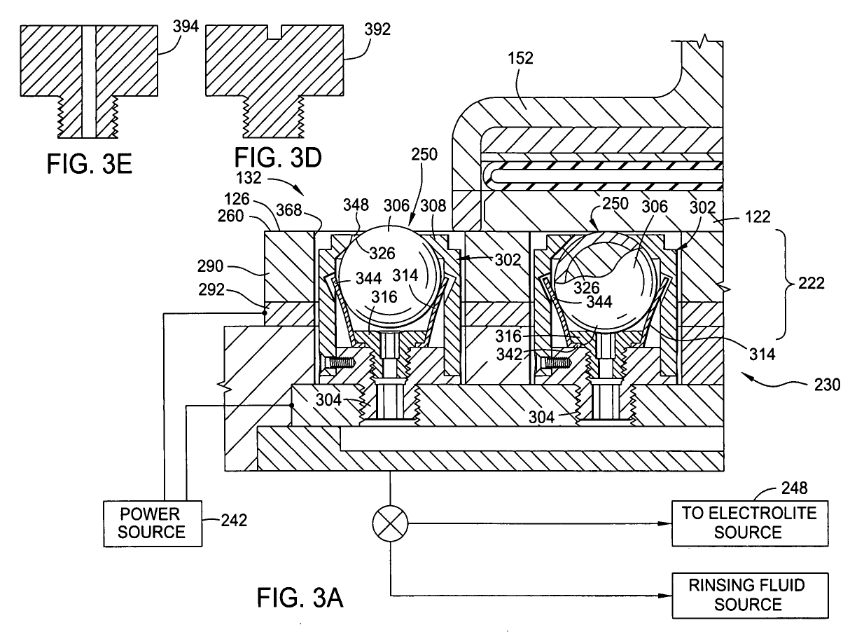

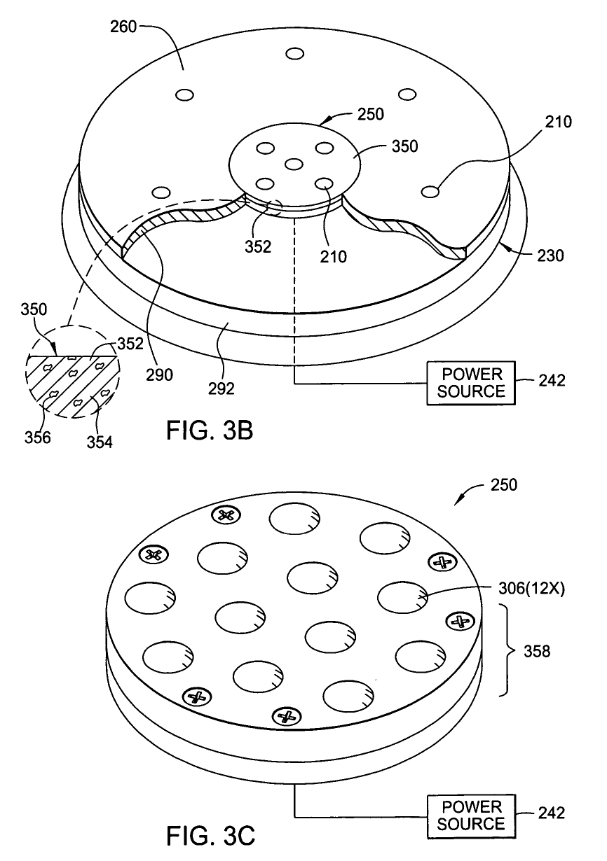

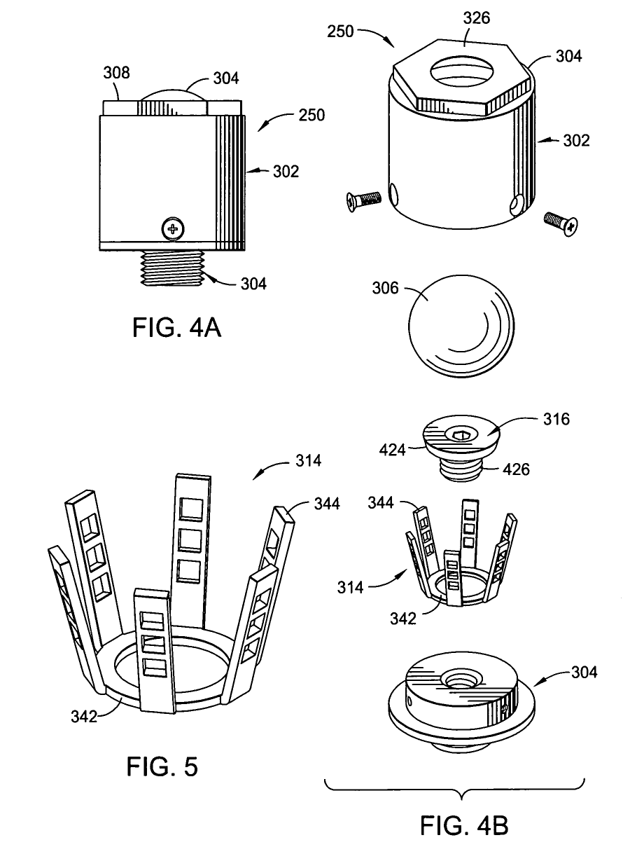

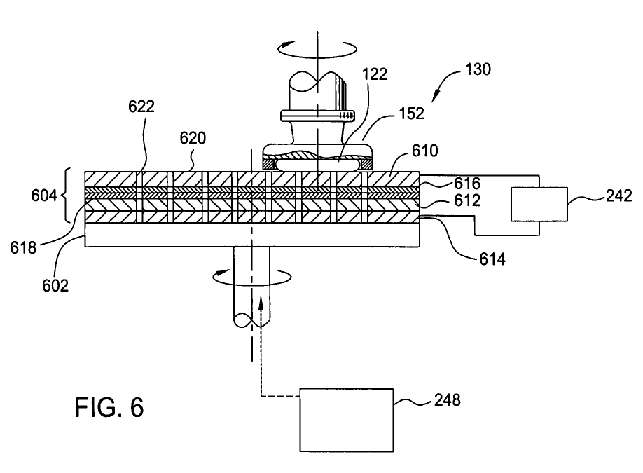

FIG. 3A is a partial sectional view of the first ECMP station 128 through two contact assemblies 250, and FIGS. 4A-C are side, exploded and sectional views of one of the contact assemblies 250 shown in FIGS. 3A. The platen assembly 230 includes at least one contact assembly 250 projecting therefrom and coupled to the power source 242 that is adapted to bias a surface of the substrate 122 during processing. The contact assemblies 250 may be coupled to the platen assembly 230, part of the processing pad assembly 222, or a separate element. Although two contact assemblies 250 are shown in FIG. 3A, any number of contact assemblies may be utilized and may be distributed in any number of configurations relative to the centerline of the platen assembly 230.

The contact assemblies 250 are generally electrically coupled to the power source 242 through the platen assembly 230 and are movable to extend at least partially through respective apertures 368 formed in the processing pad assembly 222. The positions of the contact assemblies 250 may be chosen to have a predetermined configuration across the platen assembly 230. For predefined processes, individual contact assemblies 250 may be repositioned in different apertures 368, while apertures not containing contact assemblies may be plugged with a stopper 392 or filled with a nozzle 394 (as shown in FIGS. 3D-E) that allows flow of electrolyte from the plenum 206 to the substrate. One contact assembly that may be adapted to benefit from the invention is described in U.S. Pat. No. 6,884,153, issued Apr. 26, 2005, and is hereby incorporated by reference in its entirety.

Although the embodiments of the contact assembly 250 described below with respect to FIG. 3A depicts a rolling ball contact, the contact assembly 250 may alternatively comprise a structure or assembly having a conductive upper layer or surface suitable for electrically biasing the substrate 122 during processing. For example, as depicted in FIG. 3B, the contact assembly 250 may include a pad structure 350 having an upper layer 352 made from a conductive material or a conductive composite (i.e., the conductive elements are dispersed integrally with or comprise the material comprising the upper surface), such as a polymer matrix 354 having conductive particles 356 dispersed therein or a conductive coated fabric, among others. The pad structure 350 may include one or more of the apertures 210 formed therethrough for electrolyte delivery to the upper surface of the pad assembly.

In one embodiment, each of the contact assemblies 250 includes a hollow housing 302, an adapter 304, a ball 306, a contact element 314 and a clamp bushing 316. The ball 306 has a conductive outer surface and is movably disposed in the housing 302. The ball 306 may be disposed in a first position having at least a portion of the ball 306 extending above the planarizing surface 126 and at least a second position where the ball 306 is substantially flush with the planarizing surface 126. It is also contemplated that the ball 306 may move completely below the planarizing surface 126. The ball 306 is generally suitable for electrically coupling the substrate 122 to the power source 242. It is contemplated that a plurality of balls 306 for biasing the substrate may be disposed in a single housing 358 as depicted in FIG. 3C.

The power source 242 generally provides a positive electrical bias to the ball 306 during processing. Between planarizing substrates, the power source 242 may optionally apply a negative bias to the ball 306 to minimize attack on the ball 306 by process chemistries.

The housing 302 is configured to provide a conduit for the flow of electrolyte from the source 248 to the substrate 122 during processing. The housing 302 is fabricated from a dielectric material compatible with process chemistries. A seat 326 formed in the housing 302 prevents the ball 306 from passing out of the first end 308 of the housing 302. The seat 326 optionally may include one or more grooves 348 formed therein that allow fluid flow to exit the housing 302 between the ball 306 and seat 326. Maintaining fluid flow past the ball 306 may minimize the propensity of process chemistries to attack the ball 306.

The contact element 314 is coupled between the clamp bushing 316 and the adapter 304. The contact element 314 is generally configured to electrically connect the adapter 304 and ball 306 substantially or completely through the range of ball positions within the housing 302. In one embodiment, the contact element 314 may be configured as a spring form.

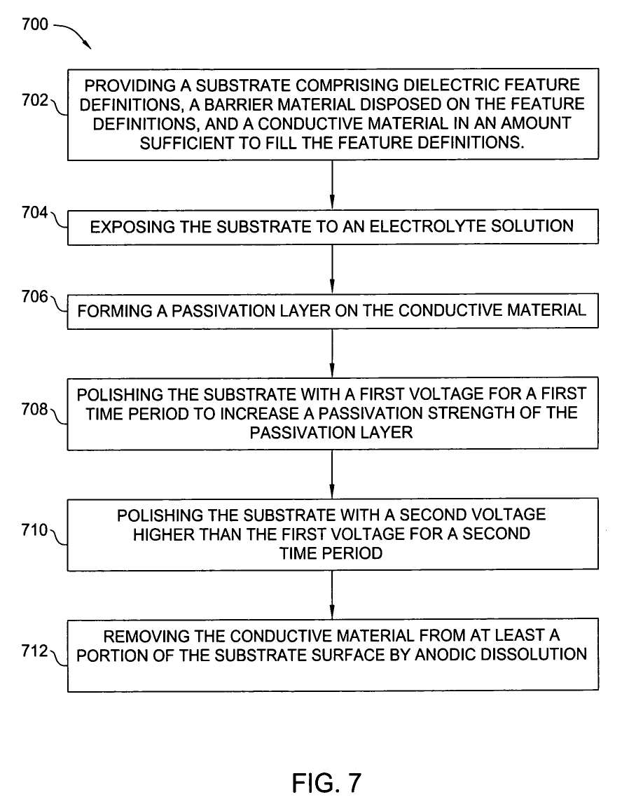

In the embodiment depicted in FIGS. 3 and 4A-C and detailed in FIG. 5, the contact element 314 includes an annular base 342 having a plurality of flexures 344 extending therefrom in a polar array. The flexure 344 is generally fabricated from a resilient and conductive material suitable for use with process chemistries. In one embodiment, the flexure 344 is fabricated from gold plated beryllium copper.

Returning to FIGS. 3A and 4A-B, the clamp bushing 316 includes a flared head 424 having a threaded post 426 extending therefrom. The clamp bushing 316 may be fabricated from either a dielectric or conductive material, or a combination thereof, and in one embodiment, is fabricated from the same material as the housing 302. The flared head 424 maintains the flexures 344 at an acute angle relative to the centerline of the contact assembly 250 so that the flexures 344 of the contact elements 314 are positioned to spread around the surface of the ball 306 to prevent bending, binding and/or damage to the flexures 344 during assembly of the contact assembly 250 and through the range of motion of the ball 306.

The ball 306 may be solid or hollow and is typically fabricated from a conductive material. For example, the ball 306 may be fabricated from a metal, conductive polymer or a polymeric material filled with conductive material, such as metals, conductive carbon or graphite, among other conductive materials. Alternatively, the ball 306 may be formed from a solid or hollow core that is coated with a conductive material. The core may be non-conductive and at least partially coated with a conductive covering.

The ball 306 is generally actuated toward the planarizing surface 126 by at least one of spring, buoyant or flow forces. In the embodiment depicted in FIG. 3, flow through the passages formed through the adapter 304 and clamp bushing 316 and the platen assembly 230 from the electrolyte source 248 urge the ball 306 into contact with the substrate during processing.

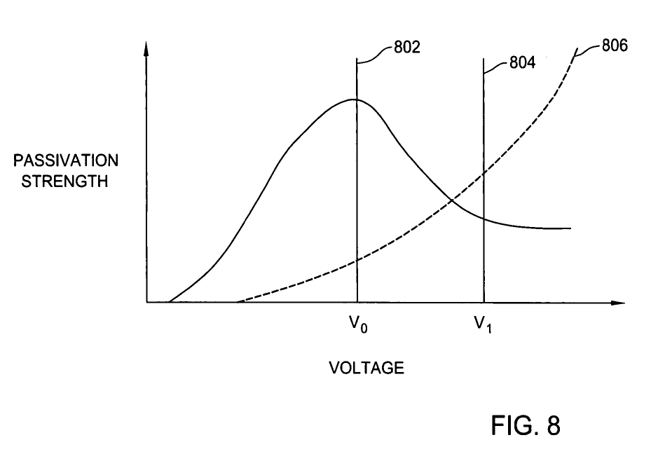

FIG. 6 is a sectional view of one embodiment of the second ECMP station 130. The first and third ECMP stations 128, 132 may be configured similarly. The second ECMP station 130 generally includes a platen 602 that supports a fully conductive processing pad assembly 604. The platen 602 may be configured similar to the platen assembly 230 described above to deliver electrolyte through the processing pad assembly 604, or the platen 602 may have a fluid delivery arm (not shown) disposed adjacent thereto configured to supply electrolyte to a planarizing surface of the processing pad assembly 604. The platen assembly 602 includes at least one of a meter 244 or sensor 254 (shown in FIG. 2) to facilitate endpoint detection.

In one embodiment, the processing pad assembly 604 includes interposed pad 612 sandwiched between a conductive pad 610 and an electrode 614. The conductive pad 610 is substantially conductive across its top processing surface and is generally made from a conductive material or a conductive composite (i.e., the conductive elements are dispersed integrally with or comprise the material comprising the planarizing surface), such as a polymer matrix having conductive particles dispersed therein or a conductive coated fabric, among others. The conductive pad 610, the interposed pad 612, and the electrode 614 may be fabricated into a single, replaceable assembly. The processing pad assembly 604 is generally permeable or perforated to allow electrolyte to pass between the electrode 614 and top surface 620 of the conductive pad 610. In the embodiment depicted in FIG. 6, the processing pad assembly 604 is perforated by apertures 622 to allow electrolyte to flow therethrough. In one embodiment, the conductive pad 610 is comprised of a conductive material disposed on a polymer matrix disposed on a conductive fiber, for example, tin particles in a polymer matrix disposed on a woven copper coated polymer. The conductive pad 610 may also be utilized for the contact assembly 250 in the embodiment of FIG. 3C.

A conductive foil 616 may additionally be disposed between the conductive pad 610 and the subpad 612. The foil 616 is coupled to a power source 242 and provides uniform distribution of voltage applied by the source 242 across the conductive pad 610. In embodiments not including the conductive foil 616, the conductive pad 610 may be coupled directly, for example, via a terminal integral to the pad 610, to the power source 242. Additionally, the pad assembly 604 may include an interposed pad 618, which, along with the foil 616, provides mechanical strength to the overlying conductive pad 610. Examples of suitable pad assemblies are described in the previously incorporated U.S. Pat. No. 6,991,528 and U.S. Patent Publication No. 2004/0020789.

Method for Electroprocessing Metal and Barrier Layers

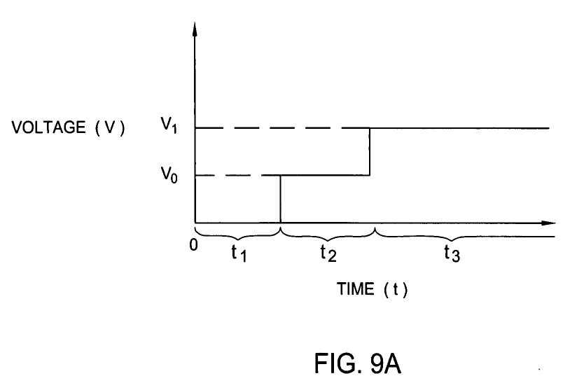

FIG. 7 depicts one embodiment of a method 700 for electroprocessing a substrate having an exposed conductive layer and an underlying barrier layer that may be practiced on the system 100 described above. The conductive layer may be tungsten, copper, a layer having both exposed tungsten and copper, and the like. The barrier layer may be ruthenium, tantalum, tantalum nitride, titanium, titanium nitride and the like. A dielectric layer, typically an oxide, generally underlies the barrier layer. The method 700 may also be practiced on other electroprocessing systems. The method 700 is generally stored in the memory 112 of the controller 108, typically as a software routine. The software routine may also be stored and/or executed by a second CPU (not shown) that is remotely located from the hardware being controlled by the CPU 110.

Although the process of the present invention is discussed as being implemented as a software routine, some of the method steps that are disclosed therein may be performed in hardware as well as by the software controller. As such, the invention may be implemented in software as executed upon a computer system, in hardware as an application specific integrated circuit or other type of hardware implementation, or a combination of software and hardware.

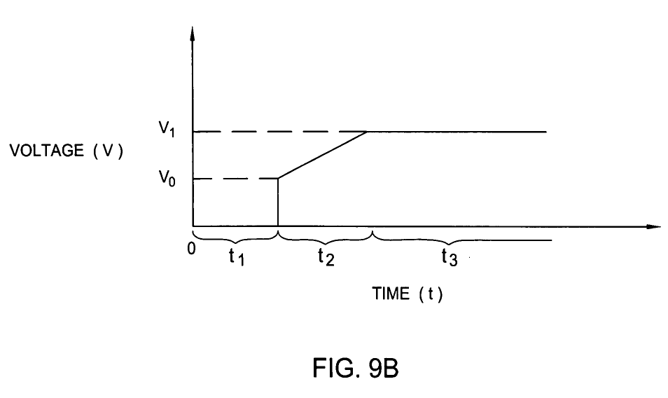

FIG. 8 is a graph depicting passivation strength-voltage characteristics of the electrochemical polishing process of the present invention. Voltage is plotted on the x-axis and passivation strength is plotted on the y-axis.

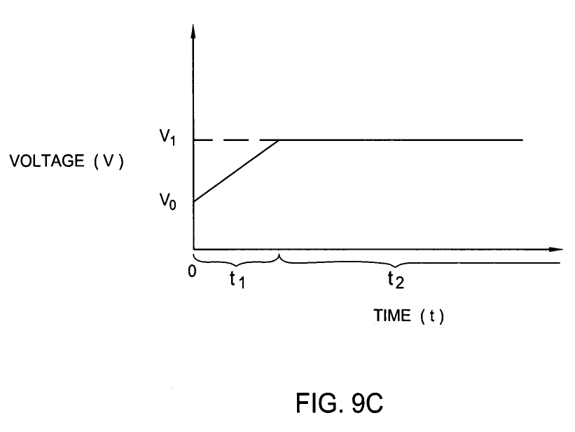

FIGS. 9A depicts a graph illustrating voltage-time characteristics of one embodiment of the electrochemical polishing process of the present invention. Voltage is plotted on the y-axis and time is plotted on the x-axis.

FIG. 9B depicts a graph illustrating voltage-time characteristics of another embodiment of the electrochemical polishing process of the present invention. Voltage is plotted on the y-axis and time is plotted on the x-axis.

FIG. 9C depicts a graph illustrating voltage-time characteristics of another embodiment of the electrochemical polishing process of the present invention. Voltage is plotted on the y-axis and time is plotted on the x-axis.

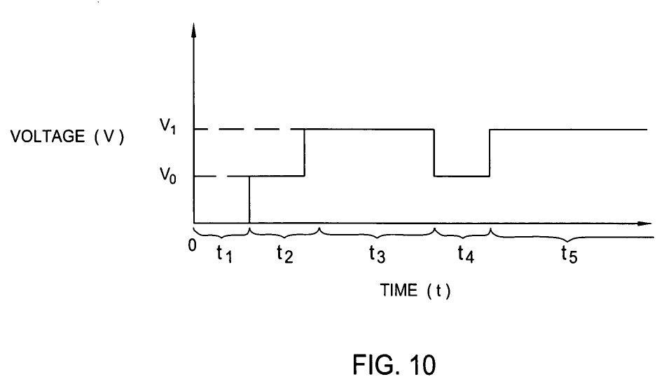

FIGS. 10 depicts a graph illustrating voltage-time characteristics of another embodiment of the electrochemical polishing process of the present invention. Voltage is plotted on the y-axis and time is plotted on the x-axis.

The method 700 begins at step 702 by providing a substrate comprising dielectric feature definitions, a barrier material disposed on the feature definitions, and a bulk conductive material in an amount sufficient to fill the feature definitions. In one embodiment, the conductive layer is a layer of copper about 4000 Å to about 20,000 Å thick. In one embodiment, the barrier layer is about 50 Å to about 250 Å thick.

Next, the substrate is exposed to an electrolyte solution in step 704. The electrolyte solution may include commercially available electrolytes. Suitable acid based electrolyte systems include, for example, sulfuric acid based electrolytes, phosphoric acid based electrolytes, perchloric acid based electrolytes, acetic acid based electrolytes, and combinations thereof. Suitable acid based electrolyte systems include an acid electrolyte, such as phosphoric acid and sulfuric acid, as well as acid electrolyte derivatives, including ammonium and potassium salts thereof. The acid based electrolyte system may also buffer the composition to maintain a desired pH level for processing a substrate.

Examples of suitable acid based electrolytes include compounds having a phosphate group (PO₄³-), such as, phosphoric acid, potassium phosphate (K₃PO₄), copper phosphate, ammonium dihydrogen phosphate (NH₄H₂PO₄), diammonium hydrogen phosphate ((NH₄)HPO₄), and compounds having a sulfate group (SO₄³-), such as sulfuric acid, ammonium hydrogen sulfate ((NH₄)₂HSO₄), copper sulfate, or combinations thereof. The invention also contemplates that conventional electrolytes known and unknown may also be used in forming the composition described herein using the processes described herein.

Alternatively, the acid based electrolyte system may be provided in an amount between about 1 and about 30 percent by weight (wt. %) or volume (vol %) of the composition to provide suitable conductivity for practicing the processes described herein. For example, dihydrogen phosphate and/or diammonium hydrogen phosphate may be present in the composition in amounts between about 15 and about 25 percent by weight or volume of the solution. Phosphoric acid may be present in concentrations up to 30 wt. %, for example, between about 2 wt.% and about 6 wt. %.

In any of the embodiments described herein, the chelating agents can bind to a conductive material, such as copper ions, increase the removal rate of metal materials, and may also be used to buffer or adjust the polishing composition to maintain a desired pH level for processing a substrate.

The one or more chelating agents can include compounds having one or more functional groups selected from the group of amine groups, amide groups, carboxylate groups, dicarboxylate groups, tri-carboxylate groups, hydroxyl groups, a mixture of hydroxyl and carboxylate groups, and combinations thereof. The one or more chelating agents may also include salts of the chelating agents described herein. The metal materials for removal, such as copper, may be in any oxidation state, such as 0, 1, or 2, before, during or after ligating with a functional group. The functional groups can bind the metal materials created on the substrate surface during processing and remove the metal materials from the substrate surface.

The polishing composition may include one or more chelating agents at a concentration between about 0.1% and about 15% by volume or weight, for example, between about 0.1% and about 4% by volume or weight. For example, about 2% by volume or weight of ethylenediamine may be used as a chelating agent.

Examples of suitable chelating agents include compounds having one ore more amine and amide functional groups, such as ethylenediamine, diethylenetriamine, diethylenetriamine derivatives, hexadiamine, amino acids, ethylenediaminetetraacetic acid, methylformamide, or combinations thereof.

Examples of suitable chelating agents having one or more carboxylate groups include citric acid, tartaric acid, succinic acid, oxalic acid, and combinations thereof. Other suitable acids having one or more carboxylate groups include acetic acid, adipic acid, butyric acid, capric acid, caproic acid, caprylic acid, glutaric acid, glycolic acid, formaic acid, fumaric acid, lactic acid, lauric acid, malic acid, maleic acid, malonic acid, myristic acid, plamitic acid, phthalic acid, propionic acid, pyruvic acid, stearic acid, valeric acid, and combinations thereof.

In any of the embodiments described herein, the inorganic or organic acid salts may perform as a chelating agent. The polishing composition may include one or more inorganic or organic salts at a concentration between about 0.1% and about 15% by volume or weight of the composition, for example, between about 0.1% and about 6% by volume or weight. For example, about 2% by volume or weight of ammonium citrate may be used in the polishing composition.

Examples of suitable inorganic or organic acid salts include ammonium and potassium salts or organic acids, such as ammonium oxalate, ammonium citrate, ammonium succinate, monobasic potassium citrate, dibasic potassium citrate, tribasic potassium citrate, potassium tartarate, ammonium tartarate, potassium succinate, potassium oxalate, and combinations thereof. Additionally, ammonium and potassium salts of the carboxylate acids described herein may also be used as the organic acid salts in the compositions described herein.

The one or more pH adjusting agents contribute to the pH adjustment of the polishing composition. The preferred pH of the polishing composition may be between about 2 and about 10, for example, between a pH of about 4 and about 6. The polishing composition may include up to about 70 wt. % of the one or more pH adjusting agents, for example, between about 0.2% and about 25% by volume or weight of the one or more pH adjusting agents. Different compounds may provide different pH levels for a given concentration, for example, the composition may include between about 0.1% and about 10% by volume of a base, such as potassium hydroxide, ammonium hydroxide, or combinations thereof, to provide the desired pH level.

The one or more pH adjusting agents that can be organic acids, for example, carboxylic acids, such as acetic acid, citric acid, oxalic acid, phosphate-containing components including phosphoric acid, ammonium phosphates, potassium phosphates, and combinations thereof, or a combination thereof. Inorganic acids, such as strong acids including sulfuric acid, nitric acid, and combinations thereof, may also be used in the polishing composition.

The one or more pH adjusting agents may also include a base, for example, potassium hydroxide, ammonium hydroxide, or combinations thereof. The amount of base used in the polishing composition is typically the amount required to adjust the pH of the composition to the desired level between about 2 and about 10.

Alternatively, the polishing composition may include a base and a compound selected from the group consisting of acetic acid, citric acid, oxalic acid, phosphoric acid, ammonium phosphates, potassium phosphates, or combinations thereof. In compositions which include both a base and a compound selected from the group identified herein, the composition may comprise between about 0.1% and about 10% by volume of the base, and between about 0.2% and about 25% by volume or weight of the compound selected from the group consisting of acetic acid, citric acid, oxalic acid, phosphoric acid, ammonium phosphates, potassium phosphates, or combinations thereof.

The polishing composition includes one or more polishing enhancing materials including abrasive particles, one or more oxidizers, and combinations thereof.

In another aspect, the electrolyte solution may also comprise a base compound, such as potassium hydroxide (KOH) for example, to adjust the pH of the solution, which may be present in an amount up to about 70 percent by weight in volume of total solution and a phosphate system, such as ammonium dihydrogen phosphate (NH₄H₂PO₄), diammonium hydrogen phosphate ((NH₄)₂HPO₄), phosphoric acid, or a mixture thereof, in amounts between about 2 and about 30 percent by weight in volume of total solution. Dihydrogen phosphate and/or diammonium hydrogen phosphate may be present in amounts between about 15 and about 25 percent by weight in volume of total solution.

One exemplary electrolyte solution contains about 8% (1-20%, 4-15%) by weight potassium phosphate monobasic, about 2% (0.2-4%, 0.5-2%) by volume ethylenediamine, about 2% (0.2-6%, 0.4-2.5%) by weight ammonium citrate, about 0.3% (0.05-0.6%, 0.1-0.4%) by weight benzotriazole; between about 0.5% and about 6% by volume of phosphoric acid to provide pH of about 5 (4-7, 4.5-6); and deionized water.

Other suitable electrolyte solutions are disclosed in U.S. Pat. No. 6,899,804, issued May 11, 2005, U.S. Patent Publication No. 2003/0178320, published on Sep. 25, 2003, U.S. patent application Ser. No. 11/312,823, entitled “Method And Composition For Electrochemical Mechanical Polishing Processing,” filed Dec. 19, 2005, U.S. patent application Ser. No. 11/123,274, entitled “Process And Composition For Conductive Material Removal By Electrochemical Mechanical Polishing,” filed May 5, 2005, and U.S. Patent Application Serial No. Unassigned, Attorney Docket No. APPM/005699.P9/PPC/CMP/CKIM), entitled “Method And Composition For Polishing A Substrate,” filed Feb. 15, 2006 which are all incorporated by reference.

At step 706, a passivation layer is formed on the conductive material. The electrolyte solution includes a passivation or suppressing agent which leads to the formation of the passivation layer. Examples of passivation or suppressing agents include corrosion inhibitors, leveling agents, viscous forming agents, or combinations thereof. Suitable corrosion inhibitors, leveling agents and viscous forming agents are further discussed in co-pending U.S. patent application Ser. No. 10/972,884, entitled “Planarization Of Substrates Using Electrochemical Mechanical Polishing,” filed Oct. 25, 2004, which is herein incorporated by reference. The passivation or suppressing layer is believed to insulate or limit the chemical and electrical reaction between the electrolyte and materials deposited on the substrate surface. The passivation or suppressing layer may be continuous or dis-continuous.

Corrosion inhibitors prevent the oxidation or corrosion of metal surfaces by forming a layer of material to reduce or minimize chemical interaction between material disposed on the substrate surface and the surrounding electrolyte. The layer of material formed by the corrosion inhibitors insulate the surface from the surrounding electrolyte, thus, suppressing or minimizing the current on the substrate surface and limiting electrochemical deposition and dissolution. Examples of corrosion inhibitors used herein may include any various organic compounds containing an azole group, such as benzotriazole, mercaptobenzotriazole, or 5-methyl-1-benzotriazole. It is believed that the azole groups, such as triazole, are effective inhibitors because the unbonded electron pair on the nitrogen atom can form coordinate covalent bonds with the conductive materials, such as copper, and become resistant to further chemical activity. Corrosion inhibitors are preferred additives to the electrolyte since corrosion inhibitors form passivation layers without oxide formation.

Alternatively, polymeric inhibitors, for non-limiting examples, polyalkylaryl ether phosphate or ammonium nonylphenol ethoxylate sulfate, may be used in replacement or conjunction with azole containing corrosion inhibitors in an amount between about 0.002% and about 1.0% by volume or weight of the composition.

At step 708, the substrate is polished with a first voltage for a first time period to build up or increase a passivation strength of the passivation layer. This increase in passivation strength is defined in terms of an increase in thickness and/or density of the passivation layer. The thickness and density of the passivation layer can dictate the extent of chemical reactions and/or amount of anodic dissolution. For example, a thicker or denser passivation layer has been observed to result in less anodic dissolution compared to thinner and less dense passivation layers. Step 708 is followed by polishing the substrate with a second voltage higher than the first voltage for a second time period at step 710. Steps 708 and 710 are described with reference to FIGS. 8, 9A, 9B, 9C and 10.

FIG. 8 is a graph depicting passivation strength-voltage characteristics of the electrochemical polishing process of the present invention. FIGS. 9A, 9B, and 10 are graphs showing various waveforms depicting voltage-time characteristics of the electrochemical polishing process of the present invention. As shown in FIG. 8, the maximum passivation strength occurs at a first voltage V₀ represented by line 802. A high rate polishing step takes place at a second voltage V₁, represented by line 804. Line 804 represents a voltage equivalent to the “conventional” ECMP voltage. The “conventional” ECMP voltage is generally between about 2.0 volts to about 5.5 volts. However, if the polishing were to start at V₁, adequate planarization would not take place and defects such as hollow metal and corrosion defects may also occur. Dashed line 806 represents the polishing rate. In one embodiment, the wafer is immersed and the voltage is turned on at time t=0. The voltage is maintained at V₀ for a first time period at a low polishing rate allowing maximum passivation to occur. Once the passivation layer is built up, the voltage is increased to V₁ where polishing takes place at a higher rate.

As shown in FIG. 9A, in one embodiment of the process, after exposure of the substrate to the electrolyte solution, a passivation layer is formed on the substrate for a time period t₁. The time period t₁ is usually less than 5 seconds and generally corresponds to the time it takes to load the wafer onto the platen. The passivation layer built up during the time period t₁ is generally very weak. After the initial formation of the passivation layer a first voltage (V₀) is applied to the substrate for a time period t₂. The time period t₂ is typically between about 5 to about 10 seconds. The thickness and/or density of the passivation layer generally increase during time period t₂. The first voltage V₀ represents a voltage where maximum passivation takes place. After strengthening of the passivation layer during time period t₂, the voltage is increased to V₁ where polishing takes place for a time period t₃. The time period t₃ is related to the applied voltage and the amount of material removed. As shown with the waveform graph in FIG. 9A, for example, the voltage V₀ is between about 1.0 V to about 3.0 V for a time period between about 5 and about 10 seconds. The voltage V₀ is then increased to voltage V₁ which is between about 2.5 V and 5.5 V for a time period t₃.

As shown in FIG. 9B, in another embodiment of the process, after exposure of the substrate to the electrolyte solution, a passivation layer is formed on the substrate for a time period t₁. The time period t₁ is usually less than 5 seconds and generally corresponds to the time it takes to load the wafer onto the platen. The passivation layer built up during the time period t₁ is generally very weak. After the initial formation of the passivation layer a first voltage (V₀) is applied to the substrate. The voltage V₀ increases linearly to V₁ over time period t₂. The time period t₂ is typically between about 5 to about 10 seconds. The thickness and density of the passivation layer generally increases during time period t₂. The first voltage V₀ represents a voltage where maximum passivation takes place. After strengthening of the passivation layer during time period t₂, polishing takes place at voltage V₁ for a time period t₃. The time period t₃ is related to the applied voltage and the amount of material removed. As shown with the waveform graph in FIG. 9B, for example, the voltage V₀ is between about 1.0 V to about 3.0 V for a time period between about 5 and about 10 seconds. The voltage V₀ is then increased to voltage V₁ which is between about 2.5 V and 5.5 V for a time period t₃.

As shown in FIG. 9C, in another embodiment of the process, while the substrate is exposed to the electrolyte solution, a passivation layer is formed on the substrate for a time period t₁. The time period t₁ is usually less than 10 seconds. During the time period t₁ the voltage is increased from V₀ to V₁. This is also known as “ramp up” voltage. The first voltage V₀ represents a voltage where maximum passivation takes place. After increasing the voltage to V₁ polishing takes place at voltage V₁ for a time period t₂. The length of time period t₂ is related to the applied voltage and the amount of material removed.

In another embodiment of the process, shown in FIG. 10, repassivation of the passivation layer takes place. As shown in FIG. 10 a passivation layer is formed on the substrate for the time period t₁. After the initial formation of the passivation layer a first voltage (V₀) is applied to the substrate for a time period t₂. The first voltage V₀ represents a voltage where maximum passivation takes place. After strengthening of the passivation layer during time period t₂, the voltage is increased to V₁ where polishing takes place for a time period t₃. As shown with the waveform graph in FIG. 10, for example, the voltage V₀ is between about 1.0 V to about 3.0 V for a time period between about 5 seconds and about 10 seconds. The voltage V₀ is then increased to voltage V₁ which is between about 2.5 V and 5.5 V for a time period between about 5 seconds and about 90 seconds. The length of the third time period t₃ is related to such factors as the applied voltage and the thickness of the material removed. After polishing at voltage V₁ for a third time period t₃, the voltage is reduced to voltage V₀ for a fourth time period. During this fourth time period repassivation or strengthening of the passivation layer takes place. After repassivation, the voltage is increased to voltage V₁ for a fifth time period t₅ where polishing of the substrate continues. Numerous other embodiments are contemplated, for example, embodiments where additional cycles are included, embodiments where the voltages for each time period vary, and embodiments where the time periods are varied.

At step 712, conductive material is removed from at least a portion of the substrate surface by anodic dissolution. Anodic dissolution of the conductive material is initiated by applying a bias between the substrate, or anode, and cathode disposed in the electrolyte to allow dissolution of conductive material, such as copper-containing materials formed thereon. The bias may include the application of a voltage of about 15 volts or less to the substrate surface. A voltage between about 0.1 volts and about 15 volts may be used to dissolve copper-containing material from the substrate surface and into the electrolyte. Under such a bias, the substrate surface acts as an anode for the dissolution of material formed thereon. Alternatively, the bias may be a current density between about 0.01 and about 40 milliamps/cm² for a 200 mm substrate. Alternatively, the bias may be applied to the processing pad assembly 222, which may be a conductive polymeric pad to electrically conduct current or power to the substrate surface during processing.

The bias applied to perform the anodic dissolution process may be varied in power and application depending on the user requirements in removing material from the substrate surface. For example, a time varying anodic potential may be provided to the substrate surface. The bias may also be applied by electrical pulse modulation techniques. The electrical pulse modification technique comprises applying a constant current density or voltage over the substrate for a first time period, than applying a constant voltage, which could be of the reverse polarity, over the substrate for a second time period, and repeating the first and second steps. The electrical pulse modification technique may use a varying potential from between about −0.1 volts and about −15 volts to between about 0.1 volts and about 15 volts. Alternatively, the bias may be a current density between about 0.01 and about 40 milliamps/cm² for a 200 mm substrate. Electrical pulses may be varied at intervals between of less than 3 seconds, for example, between about 0.2 second and 0.4 second or between 5 milliseconds and 100 milliseconds.

In operation, the substrate 122 is polished in the electrolyte solution with the processing pad assembly 222 removing at least a portion of a passivation layer from the substrate surface. At least a portion of the substrate surface is contacted to the processing pad assembly 222 during at least a portion of the process to provide mechanical interaction with the substrate surface. For example, the substrate 122 and the processing pad assembly 222 are moved in relative motion to one another, such as in a relative orbital motion, to mechanically remove at least a portion of the passivation layer formed on the substrate surface to expose the underlying conductive material. The polishing step may also remove a portion of copper-containing material disposed on the substrate surface in contact with the processing pad assembly 222.

A polishing pressure of about 6 psi or less between the processing pad assembly 222 and the substrate surface is used to remove the passivation layer and copper-containing material from the substrate surface. In one aspect, a polishing pressure of about 2 psi or less is used to remove the passivation layer (and copper-containing material) for the electrochemical mechanical polishing (ECMP) technique to planarize the substrate surface. In another aspect, a polishing pressure between about 0.05 psi and 0.5 psi, preferably 0.3 psi, is used to remove the passivation layer. For polishing low k materials, such as silicon oxycarbide and low k porous materials, a polishing pressure of about 1.5 psi or less, such as about 0.5 psi, may be used. In one embodiment of the process, at pressures of about 6 psi or less, corrosion inhibitors, leveling agents, or combinations thereof, may be used at polishing pressures of about 6 psi or less. Leveling agents may be used when the polishing pressures is about 2 psi or less.

The substrate 122 may be rotated at a carrier head or planarizing head 204 rotational speed of about 5 rpms or greater during polishing. For example, a rotational speed of the planarizing head 204 may be between about 5 rpms and about 500 rpms, with a rotational speed between about 5 rpms and about 75 rpms most commonly used. The invention contemplates a polishing apparatus providing a rotational rate greater than 120 rpms and less than 500 rpms. The platen assembly 230 may also be rotated at between about 5 rpms and about 500 rpms, with a rotational speed between about 5 rpms and 50 rpms most commonly used.

Material is removed from at least a portion of the substrate surface by anodic dissolution, mechanical abrasion, or combinations thereof, as described above. The bias is applied to the substrate surface to remove copper containing material at a rate of about 15,000 Å/min, such as between about 100 Å/min and about 15,000 Å/min. In one embodiment of the invention where the copper material to be removed is less than 5,000 Å thick, the voltage may be applied to provide a removal rate between about 100 Å/min and greater than 6,500 Å/min. The removal rate is dependent on the applied voltage and the amount of material removed among other things.

An example of the polishing process includes positioning a substrate having copper-containing material disposed thereon in a first ECMP station 128. The first ECMP station 128 contains about 8% by weight potassium phosphate monobasic, about 2% by volume ethylenediamine, about 2% by weight ammonium citrate about 0.3% by weight benzotriazole, between about 0.5% and about 6% by volume to provide a pH of about 5, and deionized water. The substrate 122 is polished with at a first voltage, approximately 2.0 volts, for a first time period, about 5 seconds. A polishing speed between about 11 rpms and about 23 rpms and a contact pressure of about 0.3 psi between the substrate 122 and the processing pad assembly 222 is provided. Conductive material is removed at a rate of about 3000 Å/min. A second voltage between about 3.0 volts and about 4.0 volts is applied to the substrate surface or conductive polishing pad for a second time period, approximately 60 seconds (depending upon voltage and the thickness of the material removed). The copper-containing material is moved at a rate greater than 6500 Å/min.

It is believed that the mechanism for planarizing the substrate 122 is as follows. A passivation layer which chemically and/or electrically insulates the surface of the substrate 122 is formed from the exposure of the surface of the substrate 122 to the corrosion inhibitor, leveling agent, or viscous forming agent, or combinations thereof, or by the deposition of a dielectric layer or organic material. A first voltage is applied to enhance the passivation strength of the passivation layer. This enhancement of passivation strength is exhibited by an increase in thickness and/or density of the passivation layer. This increased passivation strength of the passivation layer allows for polishing at a higher rate. A second voltage higher than the first voltage is applied to remove material or enhance removal of conductive material, such as copper-containing material, from the surface of the substrate 122 by anodic dissolution. However, since the passivation layer insulates or suppresses the current for anodic dissolution, mechanical abrasion is provided between the substrate 122 and processing pad assembly 222 to remove the passivation layer from areas of contact between the processing pad assembly 222 and the substrate 122, such as from peaks formed on the substrate surface from excessive deposition or topography of underlying layers, and expose the underlying copper-containing material. The passivation layer is retained in areas of minimal or no contact, such as recesses or valleys in the substrate surface. The exposed copper-containing material is then electrically connected with the electrolyte solution and may be removed by anodic dissolution.

The selective removal of the passivation layer from peaks by contact with the processing pad assembly 222 under the applied bias while retaining the passivation layer in valleys, allows for increased dissolution and/or removal of excessive copper-containing materials from passivation-free portions of the substrate surface in relation to the removal of the conductive materials underlying the passivation layer. The increased dissolution and removal of the copper-containing materials without a passivation layer formed thereon allows for increased reduction of the peaks formed on the substrate surface compared to the valleys formed thereon, resulting in enhanced planarization of the substrate surface.

Additionally, removal of material by polishing and anodic dissolution allows for the substrate surface to be planarized with lower polishing pressures (i.e., about 2 psi or less) than conventional polishing. Lower polishing pressures correspond to lower shear forces and frictional forces which make this process suitable for planarizing substrate surfaces sensitive to contact pressures between the substrate 122 and polishing pads, such as polishing low k dielectric materials, with reduced or minimal deformations and defect formation from polishing. Further, the lower shear forces and frictional forces has been observed to reduce or minimize formation of topographical defects, such as dishing and scratches, during polishing.

Following the depositing and planarizing process, the substrate may then be transferred to a polishing apparatus for further planarization of the substrate. In one aspect of the invention, a substrate that has been deposited and polished as described above is transferred to a second ECMP station 130, and residual or remaining deposited material, such as copper, is removed from the substrate surface. Residual material is broadly defined as any bulk material remaining after one or more polishing process steps has been performed on the substrate. Residual material may include copper containing material, such as copper, copper alloys, and/or doped copper as well as copper polishing by-products, such as copper oxides, removed from the substrate surface. Residual may partially or completely cover the surface a substrate, for example, a portion of the underlying barrier layer may be exposed when residual material is retained after a polishing step, or alternatively, no barrier layer may be exposed after a polishing process has been performed.

In one example, a substrate is positioned on a platen containing a fixed abrasive polishing pad, and typically includes positioning the substrate on the fixed abrasive polishing pad at polishing station (not shown). The polishing process may use an abrasive free or abrasive containing polishing composition on a conventional or fixed abrasive polishing pad described above.

The substrate may then be positioned for barrier removal in a third ECMP station 132 containing a polishing pad, which typically includes positioning a substrate on a polishing pad disposed on a platen in a polishing station. A barrier removal polishing composition is then supplied to the polishing pad and barrier layer materials are then removed from the surface of the substrate by a polishing process on the substrate. The barrier removal polishing composition may be an abrasive free composition on a conventional of fixed abrasive pad or may include high-speed chemical etching, also known as spin-etch.

The substrate may then be buffed to minimize surface defects. An example of a suitable buffing process and composition is disclosed in U.S. patent application Ser. No. 09/569,968, filed on May 11, 2000, and incorporated herein by reference to the extent not inconsistent with the invention.

Optionally, a cleaning solution may be applied to the polishing pad during or subsequent each of the polishing process to remove particulate matter and spent reagents from the polishing process as well as help minimize metal residue deposition on the polishing pads and defects formed on a substrate surface. An example of a suitable cleaning solution is ElectraClean™ commercially available from Applied Materials, Inc., of Santa Clara, Calif.

Finally, the substrate may be exposed to a post polishing cleaning process to reduce defects formed during polishing or substrate handling. Such processes can minimize undesired oxidation or other defects in copper features formed on a substrate surface. An example of such a post polishing cleaning is the application of Electra Clean™, commercially available from Applied Materials, Inc., of Santa Clara, Calif.

While the above described embodiments are directed to polishing a copper material, including copper alloys and doped copper, from a substrate, the invention contemplates application of the process described herein for polishing surfaces that may contain conductive metals, such as aluminum, tungsten, tantalum, titanium, nitrides of tungsten, tantalum, and titanium, alloys of aluminum, tungsten, tantalum, and titanium, doped aluminum, doped tungsten, doped tantalum, and doped titanium, and combinations thereof, and other materials that may deposited and/or removed by electrochemical processes, such as platinum, gold, silver, nickel and combinations thereof.

1. A method for electrochemical mechanical polishing of a substrate comprising:
providing a substrate comprising dielectric feature definitions, a barrier material disposed on the feature definitions, and a conductive material in an amount sufficient to fill the feature definitions;
exposing the substrate to an electrolyte solution;
forming a passivation layer on the conductive material;
polishing the substrate with a first voltage for a first time period to increase a passivation strength of the passivation layer;
polishing the substrate with a second voltage higher than the first voltage for a second time period, wherein the first voltage and the second voltage have a positive polarity; and
removing the conductive material from at least a portion of the substrate surface by anodic dissolution.

2. The method of claim 1, further comprising repassivating the passivation layer by polishing the substrate with a third voltage lower than the second voltage for a third time period.

3. The method of claim 1, further comprising repeating the steps of polishing the substrate with a first voltage and polishing the substrate with a second voltage higher than the first voltage for one or more cycles.

4. (canceled)

5. The method of claim 1, wherein polishing the substrate with a first voltage for a first time period to increase a passivation strength of the passivation layer comprises increasing a thickness of the passivation layer.

6. The method of claim 1, wherein polishing the substrate with a first voltage for a first time period to increase a passivation strength of the passivation layer comprises increasing a density of the passivation layer.

7. The method of claim 1, wherein the first time period is less than the second time period.

8. The method of claim 7, wherein the first time period is between about 5 seconds and about 10 seconds.

9. The method of claim 1, wherein the first voltage is between about 1.5 volts and about 3.0 volts.

10. The method of claim 1, wherein the second voltage is between about 4.5 volts and about 5.5 volts.

11. A method of processing a substrate having a conductive material layer disposed thereon, comprising:
providing the substrate to a process apparatus;
exposing the substrate to an electrolyte;
forming a current suppression layer on the substrate;
contacting the substrate to a polishing article;
providing a first relative motion between the substrate and the polishing article;
applying a first bias to the substrate for a first time period;
increasing a density of the current suppression layer;
removing at least a first portion of the conductive material layer;
providing a second relative motion between the substrate and the polishing article;
applying a second bias higher than the first bias to the substrate for a second time period, wherein the applying the first bias comprises applying a bias between about 1.5 volts and about 3.0 volts and applying the second bias comprises applying a bias between about 4.5 volts and about 5.5 volts; and
removing at least a second portion of the conductive material layer.

12. (canceled)

13. The method of claim 11, wherein the first time period is between about 5 seconds and about 10 seconds.

14. The method of claim 11, wherein the second time period is between about 5 seconds and about 90 seconds.

15. The method of claim 11, wherein the contacting the substrate to a polishing article comprises applying a pressure between the substrate and the polishing article of between about 0.1 psi and about 3.0 psi and the providing relative motion comprises rotating the polishing article between about 5 rpm and about 75 rpm and rotating the substrate between about 5 rpm and about 50 rpm.

16. The method of claim 11, wherein the electrolyte comprises:
an acid based electrolyte;
a chelating agent,
a corrosion inhibitor,
passivating polymeric material;
a pH adjusting agent;
a solvent; and
a pH between about 3 and about 10.

17. The method of claim 1, wherein the conductive material comprises copper and the barrier material comprises tantalum, tantalum nitiride, or combinations thereof.

18. The method of claim 11, wherein the removing at least a first portion of the conductive material layer occurs at a removal rate of approximately 3000 Å/minute.

19. The method of claim 11, wherein the removing at least a second portion of the conductive material layer occurs at a removal rate of approximately 6500 Å/minute.

20. A method for electrochemically and mechanically planarizing a surface of a substrate, comprising:
holding a substrate against a polishing pad of a polishing device;
applying a first potential between about 1.5 volts and about 3.0 volts for a time period between about 5 seconds and about 10 seconds between the polishing pad and the surface of the substrate being planarized; and
applying a second potential between about 4.5 volts and about 5.5 volts for a time period between about 5 seconds and about 90 seconds between the polishing pad and the surface of the substrate being planarized.
